(19) United States
(12) Patent Application Publication
(10) Pub. No.: US 2026/0131504 A1
(43) Pub. Date: May 14, 2026

(54) SPINDLE APPARATUS AND CUTTING APPARATUS FOR SEMICONDUCTOR PACKAGE

(71) Applicant: Samsung Electronics Co., Ltd., Suwon-si (KR)

(72) Inventors: Taehun Park, Suwon-si (KR); Youngrock Lee, Suwon-si (KR); Taehoon Lee, Suwon-si (KR); Seongchan Han, Suwon-si (KR)

(21) Appl. No.: 19/366,201

(22) Filed: Oct. 22, 2025

(30) Foreign Application Priority Data
Nov. 8, 2024 (KR) 10-2024-0157903

(51) Int. Cl. B28D 5/02; B28D 5/00; H01L 21/67

(52) U.S. Cl. CPC B28D 5/021; B28D 5/0064; H10P 72/0428; H10P 72/0616

(57) ABSTRACT

A spindle apparatus may include a cover; a rotation body within the cover to be rotatable about a central axis thereof and including a first end portion exposed to the outside and a second end portion opposite to the first end portion; a cutting tool on the first end portion of the rotation body; and an electrostatic discharge (ESD) prevention device on the second end portion of the rotation body. The ESD prevention device includes a charge discharge structure in at least partial contact with the second end portion of the rotation body to discharge charges accumulated in the cutting tool to the outside; a sensor above the charge discharge structure to detect whether the charge discharge structure is in contact with the rotation body; and a driver to move the charge discharge structure so that the charge discharge structure is in contact with the rotation body.

### CROSS-REFERENCE TO RELATED APPLICATION

This application claims priority under 35 U.S.C. § 119 to Korean Patent Application No. 10-2024-0157903, filed on November 8, 2024, in the Korean Intellectual Property Office (KIPO), the contents of which are herein incorporated by reference in their entirety.

### BACKGROUND

In a spindle apparatus that rotates at high speed and cuts a printed circuit board (PCB), charges may accumulate on a bit of the spindle apparatus due to friction generated during a cutting process. If charges are excessively accumulated on the bit, an electrostatic discharge (ESD) phenomenon in which a high-voltage current is discharged may occur. Electrostatic discharge may burn products, resulting in defective products.

### SUMMARY

In order to prevent electrostatic discharge, a structure for discharging charges accumulated on the bit in real time may be introduced into the spindle apparatus. In some examples, the structure may need to come into contact with a rotation body inside the spindle apparatus that rotates at high speed, and the structure may be worn due to friction with the rotation body. The spindle apparatus can be disassembled to check the wear of the charge discharge structure, which may reduce the efficiency of the process. In addition, when a spring is used to contact the structure with the rotating body, the structure may not contact the rotation body due to wear of the structure and decreased elasticity of the spring.

Example implementations provide a spindle apparatus having an electrostatic discharge prevention device that measures the degree of wear of a charge discharge structure in real time.

Example implementations relate to a spindle apparatus. More particularly, example implementations relate to a spindle apparatus including a charge discharge structure for preventing an electrostatic discharge (ESD) phenomenon.

Example implementations provide a cutting apparatus for semiconductor package including the spindle apparatus.

According to example implementations, a spindle apparatus includes a cover including a body portion and a head portion on the body portion; a rotation body within the body portion of the cover to be rotatable about a central axis of the rotation body, the rotation body including a first end portion exposed to the outside and a second end portion opposite to the first end portion; a cutting tool on the first end portion of the rotation body so as to rotate integrally with the rotation body; and an electrostatic discharge (ESD) prevention device in the head portion of the cover and on the second end portion of the rotation body. The ESD prevention device includes a charge discharge structure that is at least partially in contact with the second end portion of the rotation body and discharges charges accumulated in the cutting tool to the outside; a sensor above the charge discharge structure and configured to detect whether the charge discharge structure is in contact with the rotation body; and a driver above the charge discharge structure to move the discharge structure such that the charge discharge structure is brought into contact with the rotation body.

According to example implementations, a cutting apparatus for semiconductor package includes a loading portion configured to support a package strip, the package strip including a plurality of semiconductor packages and a connection portion connecting the plurality of semiconductor packages; a movable support above the loading portion; and a spindle apparatus movable along the movable support and configured to cut the package strip. The spindle apparatus includes a cover; a rotation body at least partially provided within the cover to be rotatable about a central axis of the rotation body, the rotation body including a first end portion exposed to the outside to face the package strip and a second end portion opposite to the first end portion; a cutting tool on the first end portion of the rotation body so as to rotate integrally with the rotation body; a charge discharge structure that is at least partially in contact with the second end portion of the rotation body and discharges charges accumulated in the cutting tool to the outside; a sensor above the charge discharge structure and configured to detect whether the charge discharge structure is in contact with the rotation body; and a driver above the charge discharge structure to move the charge discharge structure such that the charge discharge structure is brought into contact with the rotation body.

According to example implementations, a spindle apparatus includes a cover; a rotation body that is at least partially provided within the cover and is rotatable about a central axis of the rotation body, the rotation body including a first end portion exposed to the outside and a second end portion opposite to the first end portion; a cutting tool on the first end portion of the rotation body so as to rotate integrally with the rotation body; and an electrostatic discharge (ESD) prevention device within the cover and on the second end portion of the rotation body. The ESD prevention device includes a brush on the second end portion of the rotation body and having a groove that faces the rotation body to accommodate the second end portion of the rotation body; a ground terminal disposed on the brush, the ground terminal being configured to discharge charges accumulated in the cutting tool to the outside; a sensor provided on the ground terminal to detect whether the brush is in contact with the rotation body; and a driver on the sensor to move the brush such that the brush is brought into contact with the rotation body.

According to example implementations, a spindle apparatus may include a cover, a rotation body within the cover to be rotatable about a central axis of the rotation body and having a first end portion exposed to the outside and a second end portion opposite to the first end portion, a cutting tool mounted on the first end portion of the rotation body so as to rotate integrally with the rotation body, and an electrostatic discharge (ESD) prevention device provided within the cover and provided on the second end portion of the rotation body.

The ESD prevention device may include a charge discharge structure that is in at least partially contact with the second end portion of the rotation body and discharges charges accumulated in the cutting tool, a sensor provided above the charge discharge structure to detect whether the discharge structure is in contact with the rotation body, and a driver provided above the charge discharge structure to move the discharge structure so that the discharge structure is in contact with the rotation body.

Accordingly, the ESD prevention apparatus of the spindle apparatus may measure the degree of wear of the charge discharge structure in real time. Thus, since there is no need to disassemble the spindle apparatus in order to check the degree of wear of the discharge structure, the efficiency of the process can be increased.

Further, the charge discharge structure of the spindle apparatus may further include a brush provided on the second end portion of the rotation body and a ground terminal provided on the brush. The brush may include a groove that accommodates the second end portion of the rotation body.

Accordingly, since the brush directly contacts the rotation body and the ground terminal, the brush may prevent electrostatic discharge (ESD) that occurs when the brush does not contact the rotation body may be prevented from occurring. Furthermore, since the second end portion of the rotation body is accommodated in the groove of the brush, a contact area between the rotation body and the brush may be increased.

Additionally, the spindle apparatus may further include a charge measuring device that extends from the cover to the charge discharge structure.

Accordingly, the charge measuring device may measure an amount of charges accumulated in the spindle apparatus in real time.

Additionally, the cover of the spindle apparatus may include a window having a transparent material to allow observation of the discharge structure.

Accordingly, the degree of wear of the discharge structure can be visually observed through the window.

### BRIEF DESCRIPTION OF THE DRAWINGS

FIG. 1 is a perspective view illustrating a cutting apparatus for semiconductor package in accordance with example implementations.

FIG. 2 is a cross-sectional view illustrating the spindle apparatus in FIG. 1.

FIG. 3 is an enlarged cross-sectional view illustrating portion ‘M1’ in FIG. 2.

FIG. 4 is an exploded perspective view illustrating the spindle apparatus in FIG. 2.

FIGS. 5 to 11 are views illustrating a monitoring method in accordance with example implementations.

FIG. 12 is a cross-sectional view illustrating a spindle apparatus in accordance with example implementations.

FIG. 13 is an enlarged cross-sectional view illustrating ‘M3’ portion in FIG. 12.

FIG. 14 is a cross-sectional view illustrating a spindle apparatus in accordance with example implementations.

FIG. 15 is a flow chart illustrating a monitoring method in accordance with example implementations.

FIG. 16 is a cross-sectional view illustrating a spindle apparatus in accordance with example implementations.

FIG. 17 is a flow chart illustrating a monitoring method in accordance with example implementations.

FIG. 18 is a cross-sectional view illustrating a spindle apparatus in accordance with example implementations.

FIG. 19 is a perspective view illustrating a spindle apparatus in accordance with example implementations.

### DETAILED DESCRIPTION

Hereinafter, example implementations will be explained in detail with reference to the accompanying drawings.

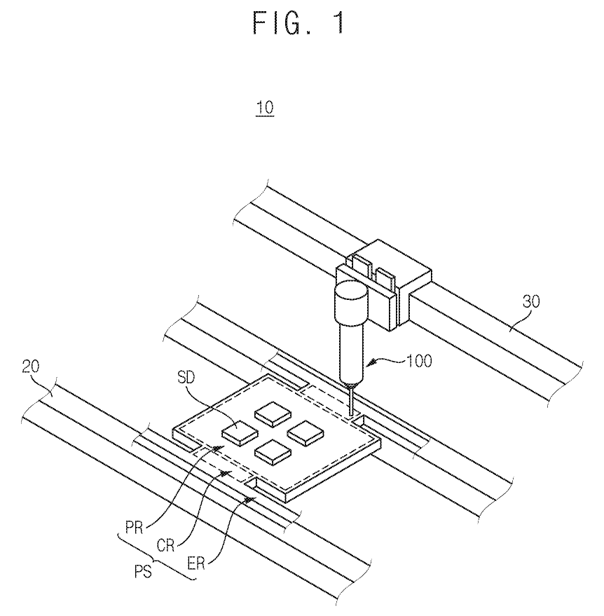

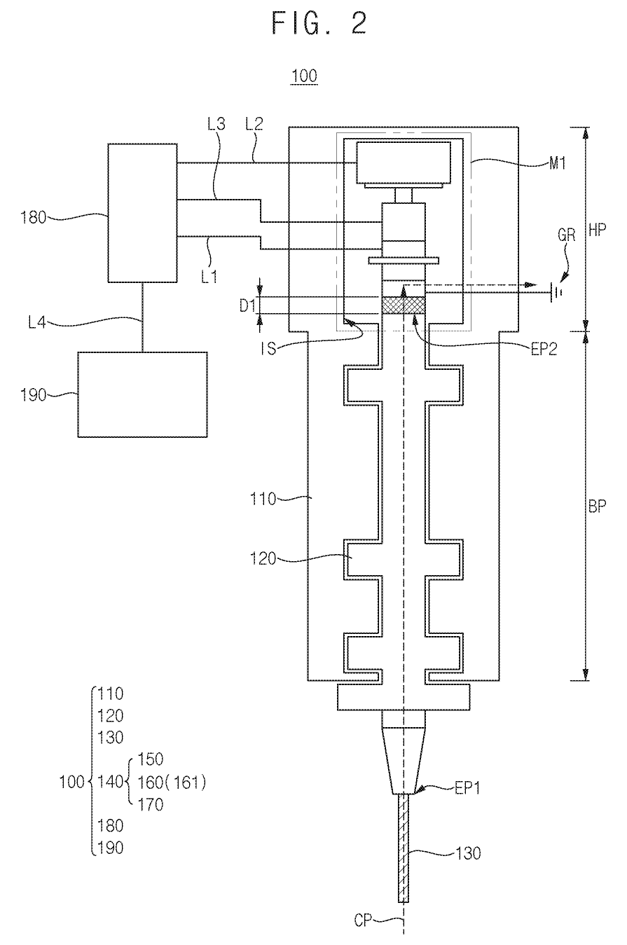

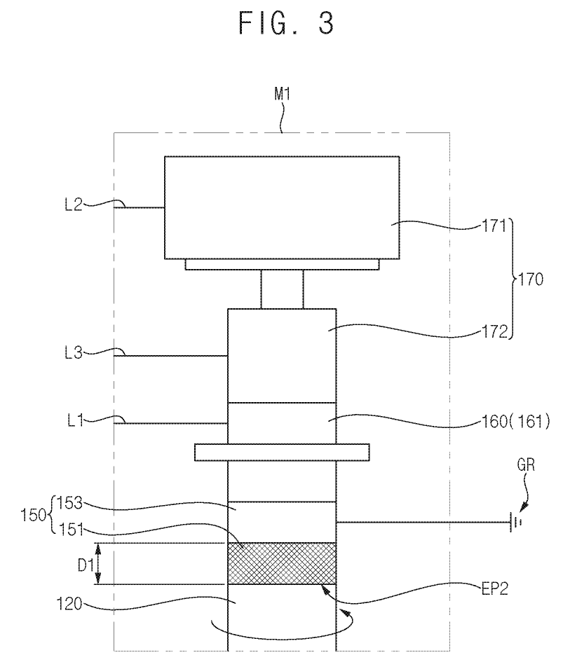

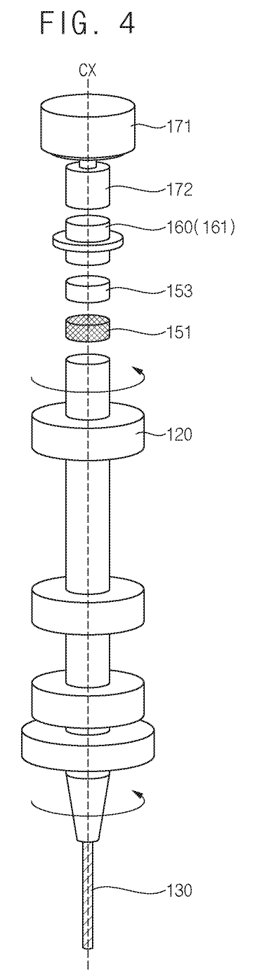

FIG. 1 is a perspective view illustrating a cutting apparatus for semiconductor package in accordance with example implementations. FIG. 2 is a cross-sectional view illustrating the spindle apparatus in FIG. 1. FIG. 3 is an enlarged cross-sectional view illustrating portion ‘M1’ in FIG. 2. FIG. 4 is an exploded perspective view illustrating the spindle apparatus in FIG. 2.

Referring to FIGS. 1 to 4, a cutting apparatus for semiconductor package 10 may include a loading portion 20 in which a substrate strip PS is mounted, a movable support 30 positioned above the loading portion 20, and a spindle apparatus 100 mounted on the movable support 30 and movable above the substrate strip PS along the movable support 30. For example, the substrate strip may include a plurality of package regions PR on which semiconductor devices SD are mounted, an edge region ER surrounding the plurality of package regions PR, and connection regions CR connecting the plurality of package regions PR and the edge region ER. The cutting apparatus for semiconductor package may be an apparatus for removing the connection regions of the substrate strip to individualize the plurality of package regions.

In example implementations, the loading portion 20 may fixedly support the edge region ER of the substrate strip PS and may move the substrate strip PS. For example, the substrate strip may be moved in a horizontal direction.

In example implementations, the movable support 30 may be configured to move in the horizontal direction or a vertical direction above the substrate strip PS that is mounted on the loading portion 20.

In example implementations, the spindle apparatus 100 may be mounted on the movable support 30 and may move along the movable support 30 in the horizontal or the vertical direction. For example, the spindle apparatus 100 may be an apparatus having a structure that rotates at a high speed to cut the substrate strip PS. For example, the spindle apparatus may move along the movable support 30 or along a guide provided on the movable support 30 and may remove the connection regions CR of the substrate strip PS.

The spindle apparatus 100 may include a cover 110, a rotation body 120 rotatable about a central axis CX of the rotation body and having a first end portion EP1 exposed to the outside and a second end portion EP2 provided within the cover 110, a cutting tool 130 mounted on the first end portion EP1 so as to rotate integrally with the rotation body 120, and an electrostatic discharge (ESD) prevention device 140 provided the second end portion EP2 of the rotation body. Additionally, the spindle apparatus 100 may further include a controller 180 for controlling the ESD prevention device 140, and an alarm device 190 for generating a warning signal in response to a signal from the controller 180. For example, the cutting tool may be a bit including a material having relatively high hardness.

The electrostatic discharge (ESD) may be a phenomenon in which excessive charge is accumulated in the cutting tool, causing a high-voltage current to sudden flow into a semiconductor manufacturing apparatus or a semiconductor device. For example, when the rotation body rotates at high speed, friction may occur between the cutting tool and an object of a cutting process, causing a charge to accumulate in the cutting tool. When a high-voltage current flows into the semiconductor device due to the accumulated charge, an internal circuit of the semiconductor device may be damaged, causing a defect.

In example implementations, the cover 110 may include a body portion BP and a head portion HP provided on the body portion BP. The cover 110 may include an internal space IS for accommodating the rotation body 120 and the ESD prevention device 140. For example, the cover may include a magnet or a coil to generate a magnetic field in the internal space.

Although the ESD prevention device 140 is illustrated as being provided within the cover 110, it will be appreciated that example implementations are not limited thereto. For example, a portion of the ESD prevention device 140 may be provided outside of the cover 110. Additionally, a power connection portion may be provided outside of the cover 110 and the cover 110 may receive power from an external power device through the power connection portion.

In example implementations, the rotation body 120 may be at least partially accommodated in the internal space IS of the cover 110. The rotation body 120 may rotate at high speed about the center axis CX due to a magnetic field generated in the interior space of the cover. For example, the rotation body may be provided with a magnet or a coil for interacting with the magnetic field of the cover.

The rotation body 120 may include the first end portion EP1 that is exposed to the outside and faces downward and the second end portion EP2 that is provided within the body portion BP of the cover 110 and is opposite to the first end portion EP1. For example, the cover 110 and the rotation body 120 may have shapes that correspond to each other. However, example implementations are not limited thereto, and the shapes of the cover 110 and the rotation body 120 may be changed.

In example implementations, the cutting tool 130 may be provided on the first end portion EP1 of the rotation body 120 and may rotate integrally with the rotation body 120. The cutting tool may be a structure that directly contacts the substrate strip PS and cuts the plurality of package regions PA. Since the cutting tool rotates at a high speed and directly contacts the substrate strip PS, an electrical charge may be accumulated in the cutting tool. For example, the cutting tool may be a bit having various shapes.

In example implementations, the ESD prevention device 140 may include a charge discharge structure 150 that is in at least partial contact with the rotation body 120 and discharges electric charges accumulated in the cutting tool, a sensor 160 configured to detect whether the rotation body 120 and the charge discharge structure 150 are in contact with each other, and a driver 170 configured to move the charge discharge structure 150 such that the rotation body 120 and the charge discharge structure 150 are brought into contact with each other.

For example, the charge discharge structure 150 may include a brush 151 provided on the second end portion EP2 of the rotation body 120 within the interior space of the cover 110 and a ground terminal 153 provided on the brush 151.

The brush 151 may include an electrostatic dissipative material to transfer the charge transferred through the cutting tool 130 and the rotation body 120 to the ground terminal 153. Additionally, the brush may include a material having relatively high strength to withstand friction with the rotation body rotating at high speed. For example, the brush may be a carbon brush. Additionally, the brush may have a surface resistance within a range of 10⁴ Ω to 10¹² Ω.

The ground terminal 153 may be a terminal connected to an external ground GR to discharge the charge transferred from the brush 151 to the outside. For example, the ground terminal 153 may be connected via a wiring to the external ground GR. The ground terminal may include a conductive metallic material.

As mentioned above, when friction occurs between the cutting tool 130 and the package strip PS during the cutting process, a charge may accumulate in the cutting tool 130. For example, the accumulated charge CP may be discharged through the cutting tool 130, the rotation body 120, the brush 151, and the ground terminal 153 to the external ground GR.

For example, the sensor 160 may include a pressure sensor 161 that is disposed between the driver 170 and the ground terminal 153 of the charge discharge structure 150. For example, the pressure sensor may measure the pressure between the driver 170 and the ground terminal 153 of the charge discharge structure 150. For example, since the rotation body 120 and the cutting tool 130 rotate together at high speed and the brush 151 is stationary, friction may occur between the rotation body 120 and the brush 151. When friction occurs between the rotation body 120 and the brush 151, the brush 151 may be worn out. When the brush 151 is worn out and a slight gap is formed between the brush 151 and the rotation body 120, the pressure measured by the pressure sensor may decrease.

For example, the driver 170 may include a transfer motor 171 provided in the head portion HP within the inner space IS of the cover 110 and a potentiometer 172 provided on the transfer motor 171. For example, the transfer motor may be integrally connected with the potentiometer, and the potentiometer may rotate and move forward by the transfer motor. In addition, the potentiometer may have an internal resistance that increases in proportion to an angle by which the potentiometer rotates.

The driver 170 may be in contact with the sensor 160 and may be able to move the sensor 160 and the charge discharge structure 150 together toward the rotation body 120. For example, the transfer motor 171 of the driver 170 may advance the potentiometer 172 to move the sensor 160 toward the rotation body 120. In addition, the ground terminal 153 and the brush 151 may be moved toward the rotation body 120 together with the sensor 160 according to the movement of the sensor 160. At this time, since the potentiometer 172 rotates together while advancing by the transfer motor 171, the resistance of the potentiometer 172 may increase.

In example implementations, the controller 180 may be connected to the sensor 160, the transfer motor 171, and the potentiometer 172, and may drive the transfer motor 171 based on data measured from the sensor 160. For example, the controller 180 may include a first signal line L1 connected to the sensor 160, a second signal line L2 connected to the transfer motor 171, and a third signal line L3 connected to the potentiometer 172.

For example, the controller 180 may receive pressure data measured by the sensor 160 (161) as a pressure sensor through the first signal line L1. For example, the pressure data may be a first pressure between the ground terminal 151 and the potentiometer 172. The first pressure may vary depending on the degree of contact between the brush 152 and the rotation body 120.

For example, the controller 180 may transmit a control signal to the transfer motor 171 through the second signal line L2 when the first pressure decreases below a predetermined pressure. Based on the control signal, the transfer motor 171 may move the potentiometer 172 toward the rotation body until the first pressure increases above the predetermined pressure. For example, when the first pressure increases above the predetermined pressure, the brush 152 and the rotation body 120 may at least partially contact each other.

In example implementations, the alarm device 190 may be connected to the controller 180 by a fourth signal line L4. The alarm device may be a device for warning the time of brush replacement based on the degree of wear of the brush.

For example, the controller 180 may receive resistance data from the potentiometer 172 by the third signal line L3. The resistance of the potentiometer 172 may increase according to the degree of rotation of the potentiometer 172. As described above, since the potentiometer 172 rotates and moves by the transfer motor 171, the resistance of the potentiometer 172 may increase as the brush 151 wears out. For example, the maximum resistance of the potentiometer 172 may be set to correspond to the brush 151 being completely worn out. The controller 180 may provide a control signal through the fourth signal line L4 when the resistance of the potentiometer 172 increases above a predetermined resistance. The alarm device 190 that has received the fourth signal may generate a warning signal to indicate the time to replace the brush 151.

As described above, the spindle apparatus 100 may include the cover 110, the rotation body 120 rotatable about the central axis and having the first end portion EP1 exposed to the outside and the second end portion EP2 provided within the cover 110, the cutting tool 130 mounted on the first end portion EP1 so as to rotate integrally with the rotation body 120, and the ESD prevention device 140 provided on the second end portion EP2. The spindle apparatus 100 may further include the controller 180 for controlling the ESD prevention device 140, and the alarm device 190 for generating a warning signal in response to a signal from the controller 180.

The ESD prevention device may include the charge discharge structure 150 that is at least partially in contact with the rotation body 120 and discharges electric charges accumulated in the cutting tool, the sensor 160 configured to detect whether the rotation body 120 and the charge discharge structure 150 are in contact with each other, and the driver 170 configured to move the charge discharge structure 150 such that the rotation body 120 and the charge discharge structure 150 are brought into contact with each other.

The charge discharge structure may include the brush 151 provided on the second end portion EP2 of the rotation body 120 within the interior space of the cover 110, and the ground terminal 153 provided on the brush 151. Additionally, the sensor 160 may include the pressure sensor 161 disposed between the driver 170 and the ground terminal 153 of the charge discharge structure 150. Further, the driver 170 may include the transfer motor 171 provided in the head portion HP within the inner space IS of the cover 110 and the potentiometer 172 provided on the transfer motor 171.

Accordingly, the ESD prevention device of the spindle apparatus may measure the degree of wear of the charge discharge structure in real time. Thus, since there is no need to disassemble the spindle apparatus in order to check the wear of the charge discharge structure, the efficiency of the process may be increased. In addition, since the brush is in direct contact with the rotation body and the ground terminal, the brush may prevent electrostatic discharge (ESD) that occurs when the brush does not contact the rotation body may be prevented from occurring.

Hereinafter, a monitoring method using the spindle apparatus 100 of FIG. 1 will be described.

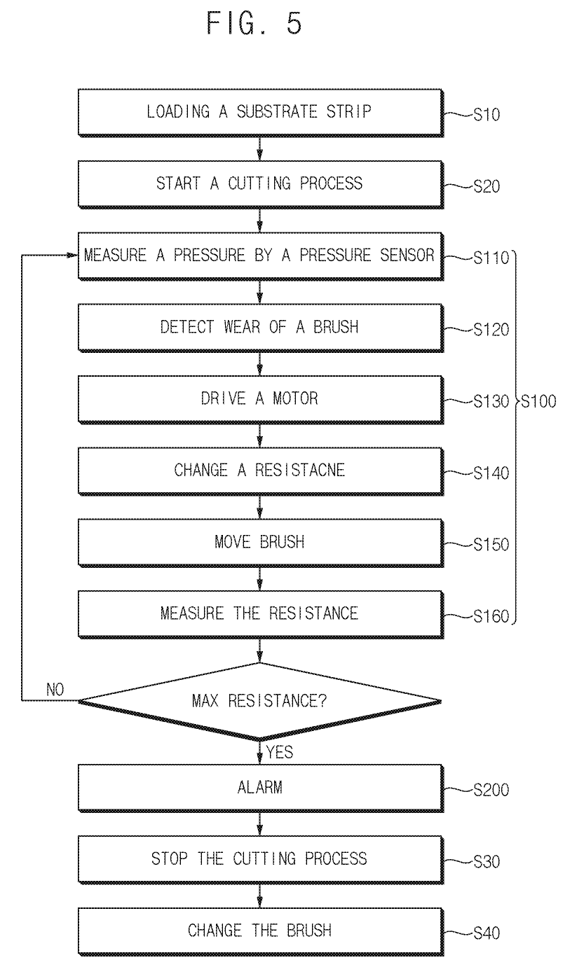

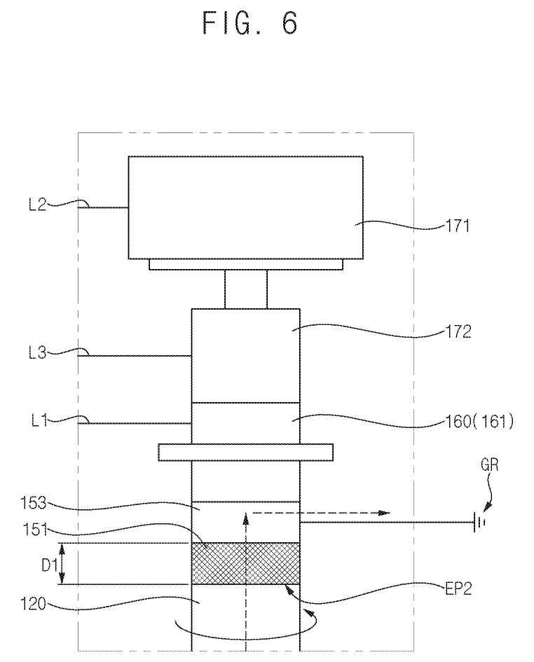

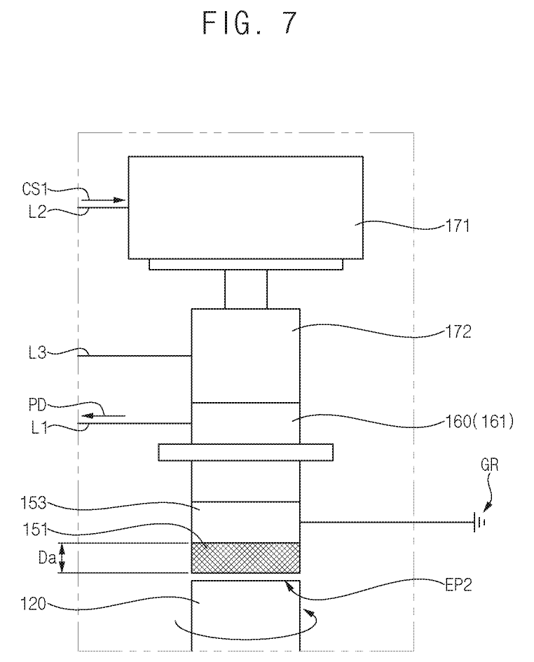

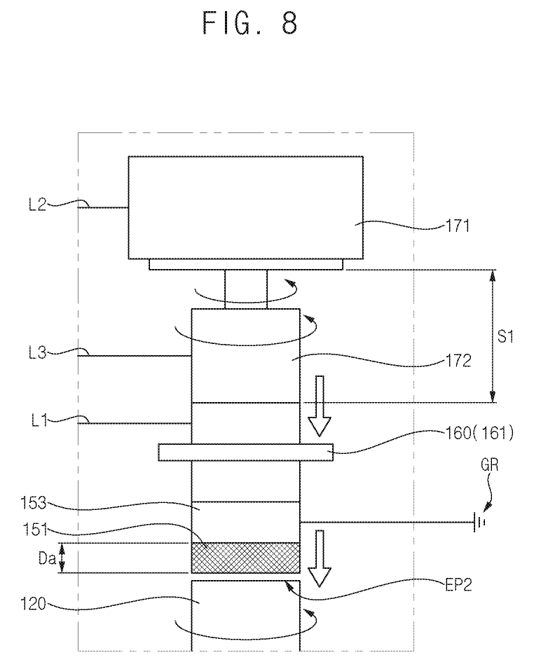

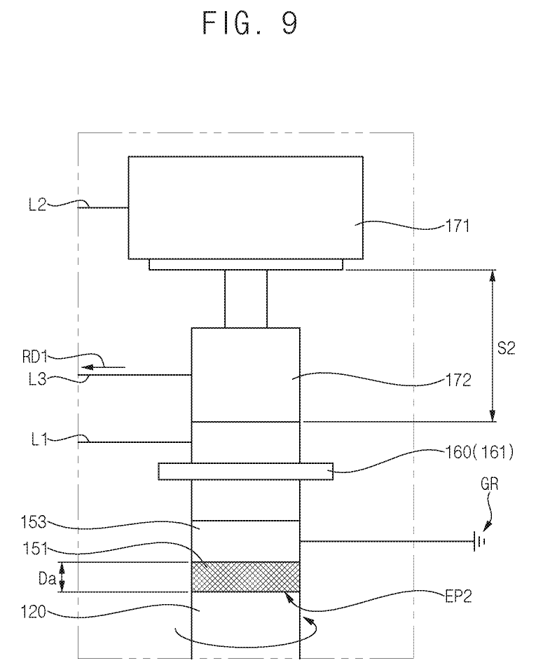

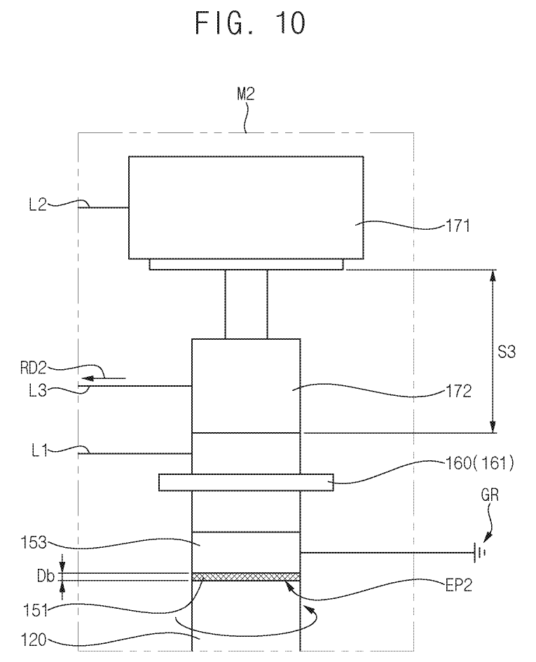

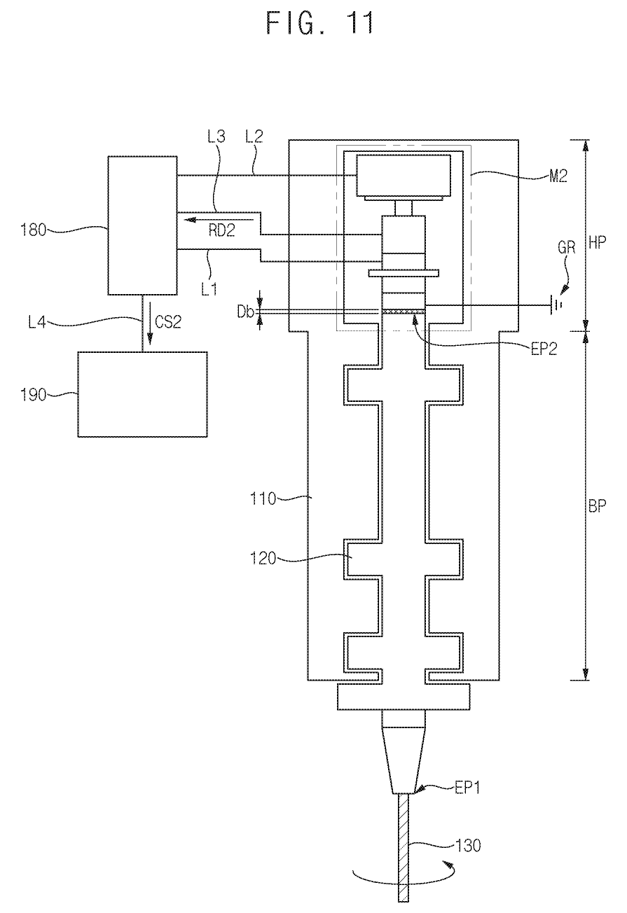

FIG. 5 is a flow chart illustrating a monitoring method in accordance with example implementations. FIG. 6 is an enlarged cross-sectional view illustrating the ESD prevention apparatus in FIG. 1. FIG. 7 is an enlarged cross-sectional view illustrating a state in which a controller applies a control signal to a transfer motor based on pressure data of a pressure sensor. FIG. 8 is an enlarged cross-sectional view illustrating a state in which the transfer motor is driven based on the control signal. FIGS. 9 to 11 are views illustrating a state in which the controller receives resistance data from a potentiometer. FIG. 10 is an enlarged cross-sectional view illustrating portion ‘M2’ in FIG. 11.

A cutting apparatus for semiconductor package utilized for the monitoring method illustrated in FIGS. 5 to 11 is substantially the same as the cutting apparatus for semiconductor package described with reference to FIGS. 1 to 4, so that identical components are denoted by the same reference numerals and repeated descriptions of identical components are omitted.

Referring to FIGS. 5 and 6, a cutting apparatus for semiconductor package 10 including a spindle apparatus 100 may be provided, and a substrate strip PS may be loaded on a loading portion 20 of the cutting apparatus for semiconductor package 10 (S10). Then, the spindle apparatus 100 may be used to perform a cutting process to individualize the substrate strip PS into a plurality of package regions (S20). At this time, an electrostatic discharge (ESD) prevention device 140 of the spindle apparatus 100 may be utilized to discharge charges accumulated in the cutting apparatus.

For example, if friction occurs between a cutting tool 130 and the package strip PS during the cutting process, charges may accumulate on a cutting tool 130. At this time, the accumulated charges may be discharged through the cutting tool 130, a rotation body 120, a brush 151, and a ground terminal 153 to an external ground GR.

In example implementations, the spindle apparatus 100 of the cutting apparatus for semiconductor package 10 may include a cover 110, the rotation body 120 that is at least partially provided within the cover 110 and is rotatable about its own central axis CX, the cutting tool 130 mounted on a first end portion EP1 of the rotation body 120 so as to rotate integrally with the rotation body 120, and the electrostatic discharge (ESD) prevention device 140 on a second end portion EP2 of the rotation body 120.

Referring to FIGS. 5, 7, and 8, a pressure sensor 161 may measure pressure between a potentiometer 172 and the ground terminal 153 (S110). The pressure sensor 161 may transfer a measured pressure data PD during the cutting process to the controller 180. The controller 180 may analyze the pressure data PD to detect the degree of wear of the brush 151 (S120). The controller 180 may apply a control signal to a transfer motor 171 to drive the transfer motor 171 (S130). The transfer motor 171 may rotate and move (or advance) the potentiometer 172 connected to a rotating shaft provided at a central portion of the transfer motor. The rotation of the potentiometer 172 may increase a resistance of the potentiometer 172 (S140). In addition, due to the movement of the potentiometer 172, the pressure sensor 161, the ground terminal 153, and the brush 151 that are sequentially provided may be moved toward the rotation body 120 (S150).

Since the rotation body 120 rotates at a high speed during the cutting process, the brush 151 may be worn out due to friction with the rotation body 120. For example, a thickness of the brush 151 may be changed from a first thickness D1 to a second thickness Da that is smaller than the first thickness D1. Although the space between the brush 151 and the rotation body 120 is illustrated as being observable with the naked eye in the figure, it will be understood that this is an example for explanation. Accordingly, the gap between the brush 151 and the rotation body 120 may be very small.

The pressure sensor 161 may be disposed between the potentiometer 172 and the ground terminal 153 and may transmit pressure data PD to the controller 180 in real time. For example, when the brush 151 is worn due to friction and a gap occurs between the brush 151 and the rotation body 120, the pressure measured by the pressure sensor 161 may decrease.

The controller 180 may apply a first control signal CS1 to the transfer motor 171 when the pressure of the pressure sensor 161 decreases below a predetermined pressure. Based on the first control signal CS1, the transfer motor 171 may move the integrally connected potentiometer 172 toward the rotation body 120. The pressure sensor 161, the ground terminal 153, and the brush 151 sequentially disposed from the potentiometer 172 may move toward the rotation body 120 together with the potentiometer 172.

Accordingly, the controller 180 may receive the pressure data PD from the pressure sensor 161 in real time, and may apply the first control signal CS1 to the transfer motor 171 based on the pressure data PD. Thus, the ESD prevention device 140 may keep the rotation body 120 and the brushes 153 in at least partial contact.

Referring to FIGS. 5, 9, and 11, the controller 180 may receive resistance data from the potentiometer 172 in real time (S160), and the controller 180 may apply a second control signal CS2 based on the resistance data to an alarm device 190, and the alarm device 190 may indicate the replacement time of the brush 151 (S200).

For example, the potentiometer 172 may move toward the rotation body 120 by the transfer motor 171, and at the same time, the potentiometer 172 may rotate by a predetermined angle in proportion to the degree of movement. In addition, the resistance of the potentiometer 172 may increase in proportion to the angle of rotation of the potentiometer 172. Accordingly, the more the potentiometer 172 moves toward the rotation body 120, the more the resistance of the potentiometer 172 may increase. For example, the maximum resistance of the potentiometer 172 may be set to a distance at which the brush 151 is completely worn out and the potentiometer 172 is closest to the rotation body 120.

The potentiometer 172 may move toward the rotation body 120 and rotate at the same time according to the degree of wear of the brush 151. The potentiometer 172 may transmit a first resistance data RD1 to the controller 180 in real time.

For example, a resistance value of the first resistance data RD1 may gradually increase. Referring again to FIG. 8, a distance from a surface of the transfer motor 171 to a surface of the potentiometer 172 may have a first distance S1. At this time, the potentiometer 172 may have a first resistance. Referring again to FIG. 9, the distance from the surface of the transfer motor 171 to the surface of the potentiometer 172 may have a second distance S2 that is greater than the first distance S1. At this time, the potentiometer 172 may have a second resistance greater than the first resistance. Referring again to FIG. 10, the distance from the surface of the transfer motor 171 to the surface of the potentiometer 172 may have a third distance S3 as a maximum distance greater than the second distance S2. At this time, the potentiometer 172 may have a third resistance as a maximum resistance greater than the second resistance. Additionally, the brush 151 may be worn to the maximum, so that the thickness of the brush 151 may have a third thickness Db as a minimum thickness.

The controller 180 may receive a second resistance data RD2 from the potentiometer 172, and the controller 180 may apply a second control signal CS2 to the alarm device 190. For example, the second resistance data may be data indicating that the resistance of the potentiometer 172 has the third resistance as the maximum resistance. Then, the alarm device 190 may display a warning signal based on the second control signal CS2. Then, the cutting process may be stopped (S30) and the brush 151 may be replaced (S40).

Then, the cutting process may be stopped (S30) and the brush 151 may be replaced (S40).

Accordingly, the monitoring method in accordance with example implementations may measure in real time whether there is contact between the rotation body 120 and the brush 151 during the cutting process and maintain the contact between the rotation body 120 and the brush 151 through the transfer motor 171. Thus, electrostatic discharge (ESD) that occurs when the rotation body 120 and the brush 151 are separated may be continuously prevented.

Further, the monitoring method in accordance with example implementations may automatically detect the replacement time of the brush 151 by measuring in real time the resistance of the potentiometer 172 that changes according to the degree of wear of the brush 151.

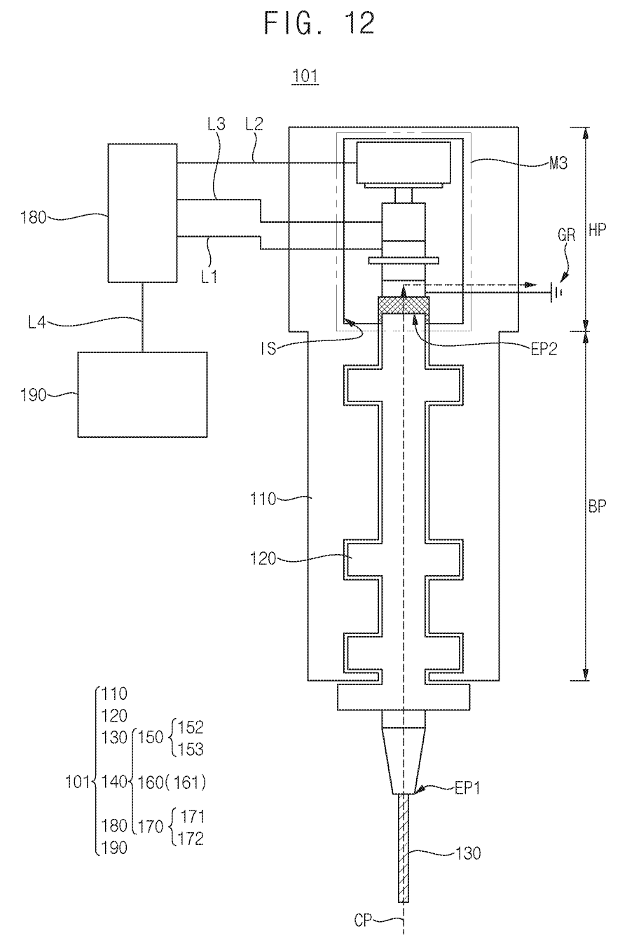

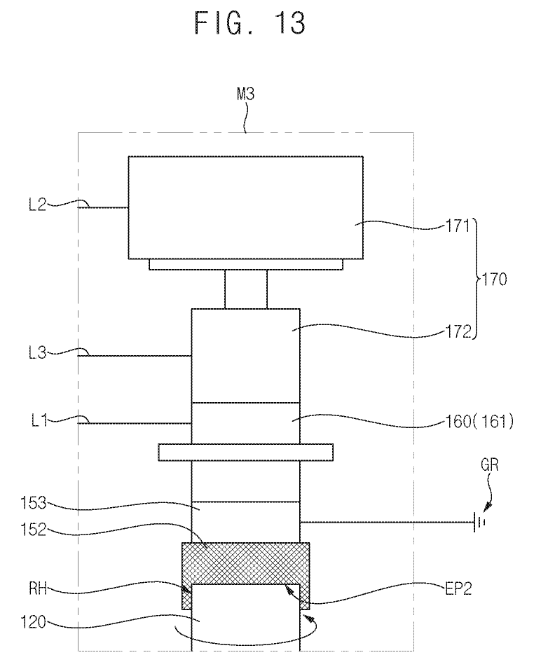

FIG. 12 is a cross-sectional view illustrating a spindle apparatus in accordance with example implementations. FIG. 13 is an enlarged cross-sectional view illustrating portion ‘M3’ in FIG. 12.

The spindle apparatus 101 illustrated in FIGS. 12 and 13 is substantially the same as the spindle apparatus 100 described with reference to FIGS. 1 to 4, except for a brush, so identical components are denoted by the same reference numerals, and repeated descriptions of identical components are omitted.

In example implementations, a spindle apparatus 101 may include a cover 110, a rotation body 120 rotatable about a central axis CX of the rotation body 120 and having a first end portion EP1 exposed to the outside and a second end portion EP2 provided within the cover 110, a cutting tool 130 mounted on the first end portion EP1 so as to rotate integrally with the rotation body 120, and an electrostatic discharge (ESD) prevention device 140 mounted on the second end portion EP2. The spindle apparatus 101 may further include a controller 180 for controlling the ESD prevention device 140, and an alarm device 190 for generating a warning signal in response to a signal from the controller 180.

In example implementations, the ESD prevention device 140 may include a charge discharge structure 150 that is at least partially in contact with the rotation body 120 and discharges electric charges accumulated in a cutting tool, a sensor 160 configured to detect whether the rotation body 120 and the charge discharge structure 150 are in contact with each other, and a driver 170 configured to move the charge discharge structure 150 such that the rotation body 120 and the charge discharge structure 150 are brought into contact with each other.

In example implementations, the charge discharge structure 150 may include a brush 152 that receives the second end portion EP2 of the rotation body 120 within an interior space of the cover 110, and a ground terminal 153 provided on the brush 152.

For example, the brush 152 may include a groove RH facing the rotation body 120. The second end portion EP2 of the rotation body 120 may be received in the groove RH of the brush 152.

Accordingly, a contact area between the rotation body 120 and the brush 152 may increase, so that a risk of electrostatic discharge occurring due to the rotation body 120 and the brush 152 not being in contact may be reduced or prevented.

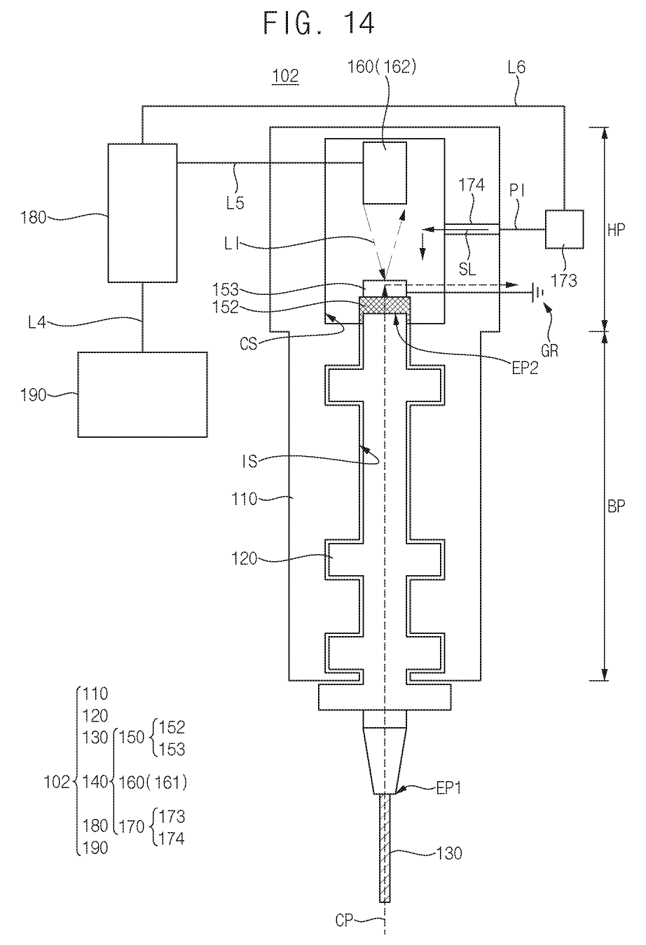

FIG. 14 is a cross-sectional view illustrating a spindle apparatus in accordance with example implementations.

The spindle apparatus 102 illustrated in FIG. 14 is substantially the same as the spindle apparatus 100 described with reference to FIGS. 1 to 4, except for a brush, a sensor, and a driver, so identical components are denoted by the same reference numerals and repeated descriptions of identical components are omitted.

In example implementations, a spindle apparatus 102 may include a cover 110, a rotation body 120 rotatable about a central axis CX of the rotation body and having a first end portion EP1 exposed to the outside and a second end portion EP2 provided within the cover 110, a cutting tool 130 mounted on the first end portion EP1 so as to rotate integrally with the rotation body 120, and an electrostatic discharge (ESD) prevention device 140 mounted on the second end portion EP2. The spindle apparatus 101 may further include a controller 180 for controlling the ESD prevention device 140, and an alarm device 190 for generating a warning signal in response to a signal from the controller 180.

In example implementations, the ESD prevention device 140 may include a charge discharge structure 150 that is at least partially in contact with the rotation body 120 and discharges electric charges accumulated in a cutting tool, a sensor 160 configured to detect whether the rotation body 120 and the charge discharge structure 150 are in contact with each other, and a driver 170 configured to move the charge discharge structure 150 such that the rotation body 120 and the charge discharge structure 150 are brought into contact with each other.

In example implementations, the charge discharge structure 150 may include a brush 152 having a groove RH that receives the second end portion EP2 of the rotation body 120 within an interior space of the cover 110, and a ground terminal 153 provided on the brush 152.

In example implementations, the sensor 160 may include a laser sensor 162 provided within a head portion HP of the cover 110 and spaced apart in a vertical direction from the ground terminal 153. For example, the laser sensor may be a sensor capable of measuring a vertical distance from the laser sensor 162 to the ground terminal 153 by irradiating light LI to the ground terminal 153 and receiving light LI reflected from the ground terminal 153.

For example, the controller 180 may receive distance data from a fifth signal line L5 connected to the laser sensor 162. The controller 180 may analyze a change in the data to detect the degree of wear of the brush 152.

In example implementations, the driver 170 may include a hydraulic transfer device 173 for injecting fluid into the inner space IS to change the pressure in the inner space IS. The hydraulic transfer device 173 may include a fluid passage 174 that is provided in the head portion HP and is in fluid communication with the inner space IS.

For example, the internal space IS may include a sealed space CS provided within the head portion HP of the cover 110. The cover 110 and the brush 152 may define the sealed space CS. The fluid passage 174 may be provided between the sealed space CS and the hydraulic transfer device 173 and may be in fluid communication with a connecting pipe PI of the sealed space CS and the hydraulic transfer device 173.

The controller 180 may apply a control signal to the hydraulic transfer device 173 through the sixth signal line L6 connected to the hydraulic transfer device 173 to adjust the pressure inside the sealed space CS. The controller 180 may maintain or change the pressure inside the sealed space CS to a constant level so that the brush 152 and the rotation body 120 come into contact with each other.

As mentioned above, the spindle apparatus 102 may include the laser sensor 162 capable of measuring the vertical distance from the laser sensor 162 to the ground terminal 153, and the hydraulic transfer device 173 for controlling the pressure inside the sealed space CS so that the brush 152 and the rotation body 120 come into contact with each other.

Accordingly, the hydraulic transfer device 173 may maintain contact between the rotation body 120 and the brush 152. Thus, electrostatic discharge (ESD) that occurs when the rotation body 120 and the brush 152 are separated may be continuously prevented.

Further, the laser sensor 162 may detect the degree of wear of the brush 152 to determine the time for replacing the brush 152.

Hereinafter, a monitoring method using the spindle apparatus 102 in FIG. 14 will be described.

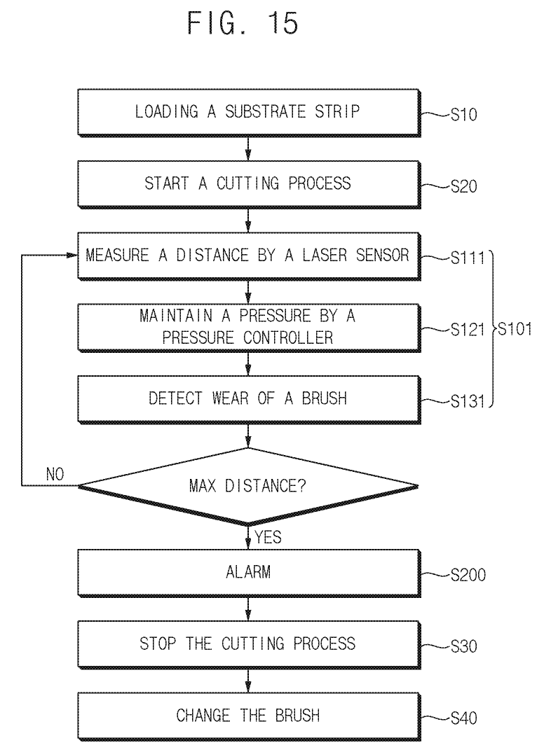

FIG. 15 is a flow chart illustrating a monitoring method in accordance with example implementations.

Since a spindle apparatus utilized for the monitoring method illustrated in FIG. 15 is substantially the same as the spindle apparatus described with reference to FIG. 14, identical components are denoted by the same reference numerals, and repeated descriptions of identical components are omitted.

Referring to FIG. 15, a laser sensor 162 of an electrostatic discharge (ESD) prevention device 140 may be utilized to measure a vertical distance from the laser sensor 162 to a ground terminal 153 in real time (S111).

Additionally, by using a hydraulic transfer device 173 of the ESD prevention device 140, the pressure inside a sealed space CS of a cover 110 may be kept or changed to so that the brush 152 and the rotation body 120 come into contact with each other (S121).

Then, a controller 180 may analyze distance data received from the laser sensor 162 to determine the degree of wear of the brush 152 (S131).

When the distance measured from the laser sensor 162 reaches a maximum distance, the controller 180 may transmit a control signal to an alarm device 190 to issue a warning (S200). Then, the cutting process may be stopped (S30) and the brush 152 may be replaced (S40).

Thus, using the monitoring method in accordance with example implementations, the degree of wear of the brush may be measured in real time and the time to replace the brush may be detected.

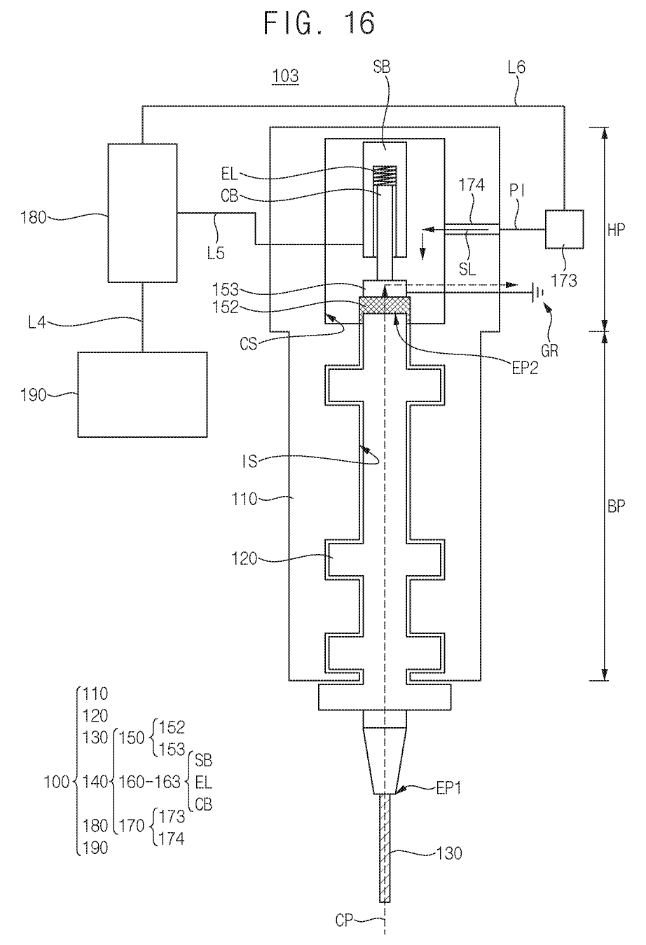

FIG. 16 is a cross-sectional view illustrating a spindle apparatus in accordance with example implementations.

The spindle apparatus 103 illustrated in FIG. 16 is substantially the same as the spindle apparatus 102 described with reference to FIG. 14, except for a contact-type distance sensor 163, so identical components are denoted by the same reference numerals and repeated descriptions of identical components are omitted.

In example implementations, a sensor 160 may include a contact-type distance sensor 163 that comes into contact with a ground terminal 153 and is able to measure a distance to the ground terminal 153. For example, the contact-type distance sensor may be a sensor that comes into contact with a specific structure, and as the distance to the specific structure changes, the contact portion moves together and specifically measures the distance to the specific structure.

For example, the contact-type distance sensor 163 may include a sensor body portion SB having a receiving space, a contact bar CB disposed within the receiving space of the sensor body portion SB, and an elastic portion EL disposed between the contact bar CB and the sensor body portion SB.

The contact bar CB may move together with the ground terminal 153 by the elastic portion EL fixed to an end portion of the ground terminal 153 when the ground terminal 153 moves. Thus, the contact bar CB may maintain contact with the ground terminal 153.

The contact-type distance sensor 163 may detect the movement of the contact bar CB and measure the distance to the ground terminal 153.

Accordingly, the contact-type distance sensor 163 may detect the degree of wear of the brush 152 and determine the time for replacing the brush.

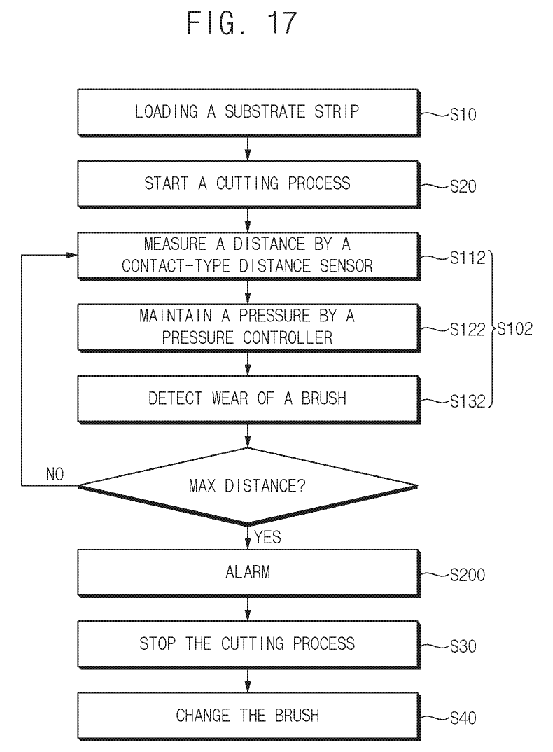

FIG. 17 is a flow chart illustrating a monitoring method in accordance with example implementations.

The spindle apparatus utilized for the monitoring method illustrated in FIG. 17 is substantially the same as the spindle apparatus described with reference to FIG. 16, so identical components are denoted by the same reference numerals and repetitive descriptions of identical components are omitted.

Referring to FIG. 17, a contact-type distance sensor 163 of an electrostatic discharge (ESD) prevention device 140 may be utilized to measure a vertical distance from the contact-type distance sensor 163 to a ground terminal 153 in real time (S112).

Additionally, by using a hydraulic transfer device 173 of the ESD prevention device 140, the pressure inside a sealed space CS of a cover 110 may be controlled such that a brush 152 and a rotation body 120 come into contact with each other. For example, the pressure inside the sealed space CS may be kept constant or changed by injecting air into the sealed space CS (S122).

Then, the controller 180 may analyze distance data received from the contact-type distance sensor 163 to determine the degree of wear of the brush 152 (S132).

When the distance measured from the contact-type distance sensor 163 reaches a maximum distance, the controller 180 may transmit a control signal to an alarm device 190 to issue a warning (S200). Then, a cutting process may be stopped (S30) and the brush 152 may be replaced (S40).

Thus, using the monitoring method in accordance with example implementations, the degree of wear of the brush may be measured in real time and the time to replace the brush may be detected.

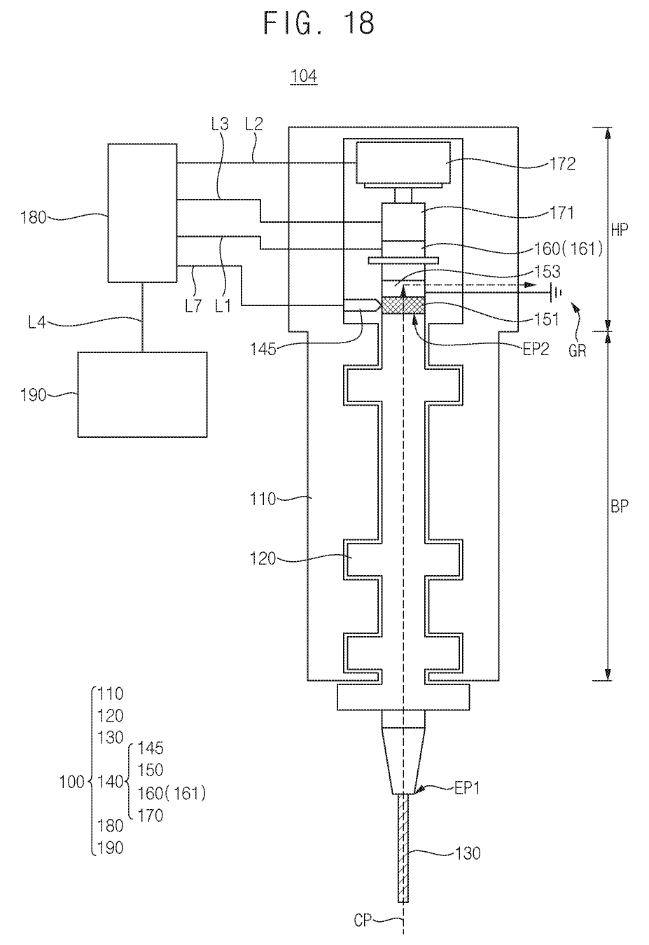

FIG. 18 is a cross-sectional view illustrating a spindle apparatus in accordance with example implementations.

The spindle apparatus 104 illustrated in FIG. 18 is substantially the same as the spindle apparatus 100 described with reference to FIGS. 1 to 4, except for a charge measuring device 145, so identical components are denoted by the same reference numerals and repeated descriptions of identical components are omitted.

In example implementations, a spindle apparatus 104 may include a cover 110, a rotation body 120 rotatable about a central axis CX of the rotation body and having a first end portion EP1 exposed to the outside and a second end portion EP2 provided within the cover 110, a cutting tool 130 mounted on the first end portion EP1 so as to rotate integrally with the rotation body 120, and an electrostatic discharge (ESD) prevention device 140 mounted on the second end portion EP2. The spindle apparatus 104 may further include a controller 180 for controlling the ESD prevention device 140, and an alarm device 190 for generating a warning signal in response to a signal from the controller 180.

In example implementations, the ESD prevention device 140 may include a charge discharge structure 150 that is at least partially in contact with the rotation body 120 and discharges electric charges accumulated in a cutting tool, a sensor 160 configured to detect whether the rotation body 120 and the charge discharge structure 150 are in contact with each other, and a driver 170 configured to move the charge discharge structure 150 such that the rotation body 120 and the charge discharge structure 150 are brought into contact with each other. The ESD prevention device 140 may further include a charge measuring device 145 extending from a first side portion of the cover 110 to the charge discharge structure 150.

In example implementations, the charge measuring device 145 may be provided in an interior space of the cover 110 and may extend to the brush 151 such that an end portion of the charge measuring device 145 is in contact with the brush 151.

The charge measuring device may measure a voltage difference between the brush 151 and the ground GR of an external device, and the controller 180 may receive voltage data to measure the accumulated charge.

A portion of the charge measuring device 145 may be connected to the ground GR of the external device.

Accordingly, the charge measuring device 145 of the spindle apparatus 104 may measure an amount of charge accumulated on the spindle apparatus 104 in real time.

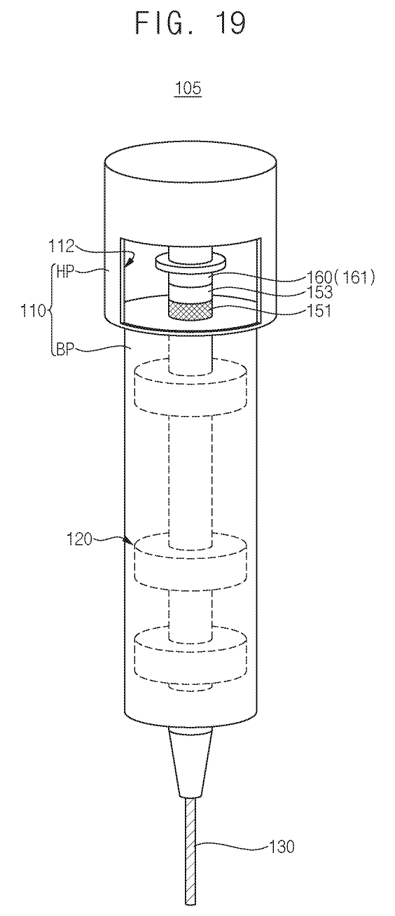

FIG. 19 is a perspective view illustrating a spindle apparatus in accordance with example implementations.

The spindle apparatus 105 illustrated in FIG. 19 is substantially identical to the spindle apparatus described with reference to FIGS. 1 to 4, except for a window, so identical components are denoted by the same reference numerals, and repeated descriptions of identical components are omitted.

In example implementations, a spindle apparatus 104 may include a cover 110, a rotation body 120 rotatable about a central axis CX of the rotation body and having a first end portion EP1 exposed to the outside and a second end portion EP2 provided within the cover 110, a cutting tool 130 mounted on the first end portion EP1 so as to rotate integrally with the rotation body 120, and an electrostatic discharge (ESD) prevention device 140 mounted on the second end portion EP2. The spindle apparatus 101 may further include a controller 180 for controlling the ESD prevention device 140, and an alarm device 190 for generating a warning signal in response to a signal from the controller 180.

In example implementations, the cover 110 may include a window 112 provided in a portion of a head portion HP. For example, the window may include a transparent material so that the degree of wear of the brush 151 can be observed with the naked eye.

Thus, the window 112 of the spindle apparatus 104 may observe the degree of wear of the brush 151 with the naked eye without stopping the cutting process and disassembling the spindle apparatus 104, thereby increasing the efficiency of the process.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in example implementations without materially departing from the novel teachings and advantages of the present invention. Accordingly, all such modifications are intended to be included within the scope of example implementations as defined in the claims.

What is claimed is:

1. A spindle apparatus, comprising:
a cover including a body portion and a head portion on the body portion;
a rotation body within the body portion of the cover, the rotation body being configured to rotate, the rotation body including a first end portion exposed to an outside of the cover and a second end portion opposite to the first end portion;
a cutting tool on the first end portion of the rotation body and configured to rotate with the rotation body; and
an electrostatic discharge (ESD) prevention device at the head portion of the cover and on the second end portion of the rotation body,
wherein the ESD prevention device includes:
a charge discharge structure that is at least partially in contact with the second end portion of the rotation body and configured to discharge charges accumulated in the cutting tool;
a sensor configured to detect that the charge discharge structure is in contact with the rotation body; and
a driver configured to move the charge discharge structure to thereby cause the charge discharge structure to contact with the rotation body.

2. The spindle apparatus of claim 1, wherein the charge discharge structure includes:
a brush in contact with the second end portion of the rotation body; and
a ground terminal between the brush and the sensor, the ground terminal being connected with an external ground.

3. The spindle apparatus of claim 2, comprising:
a charge measuring device in contact with the brush and configured to measure a voltage difference between the brush and the ground terminal.

4. The spindle apparatus of claim 1, wherein the sensor includes a pressure sensor between the charge discharge structure and the driver, the pressure sensor being configured to measure a pressure between the charge discharge structure and the driver.

5. The spindle apparatus of claim 4, wherein the driver includes:
a potentiometer in contact with the sensor and having an internal resistance that is configured to increase in proportion to a rotation angle; and
a transfer motor configured to rotate the potentiometer and move the potentiometer toward the rotation body to maintain contact between the charge discharge structure and the rotation body according to the pressure measured by the pressure sensor.

6. The spindle apparatus of claim 5, comprising:
a controller configured to detect a change in the internal resistance of the potentiometer; and
an alarm device configured to generate a warning signal according to a control signal from the controller based on the internal resistance exceeding a predetermined resistance.

7. The spindle apparatus of claim 1, wherein the sensor includes a laser sensor configured to measure a distance between the sensor and the charge discharge structure by irradiating a light toward the charge discharge structure.

8. The spindle apparatus of claim 1, wherein the sensor includes a contact type distance sensor that includes a sensor contact portion at least partially in contact with the charge discharge structure and an elastic portion provided at an end portion of the sensor contact portion.

9. The spindle apparatus of claim 1, wherein the driver includes a hydraulic transfer device, and the hydraulic transfer device includes a fluid passage provided in the head portion of the cover and in fluid communication with an internal space within the head portion, the hydraulic transfer device being configured to adjust a pressure within the head portion of the cover to maintain contact between the charge discharge structure and the rotation body.

10. The spindle apparatus of claim 1, wherein the head portion of the cover includes a window including a transparent material that is configured to allow observation of the charge discharge structure.

11. A cutting apparatus for semiconductor package comprising:
a loading portion configured to support a package strip, the package strip including a plurality of semiconductor packages and a connection portion connecting the plurality of semiconductor packages;
a movable support above the loading portion; and
a spindle apparatus movable along the movable support and configured to cut the package strip,
wherein the spindle apparatus includes:
a cover;
a rotation body at least partially provided within the cover and configured to rotate, the rotation body including a first end portion exposed to an outside of the cover and facing the package strip and a second end portion opposite to the first end portion;
a cutting tool on the first end portion of the rotation body, the cutting tool configured to rotate with the rotation body;
a charge discharge structure that is at least partially in contact with the second end portion of the rotation body and configured to discharge charges accumulated in the cutting tool;
a sensor configured to detect that the charge discharge structure is in contact with the rotation body; and
a driver configured to move the charge discharge structure to thereby cause the charge discharge structure to contact with the rotation body.

12. The cutting apparatus of claim 11, wherein the charge discharge structure includes,
a brush in contact with the second end portion of the rotation body; and
a ground terminal between the brush and the sensor, the ground terminal being connected with an external ground.

13. The cutting apparatus of claim 12, wherein the brush includes an electrostatic dissipative material to transfer the charges to the ground terminal.

14. The cutting apparatus of claim 11, wherein the spindle apparatus includes a controller configured to apply a control signal to the driver based on a measurement signal from the sensor so that the charge discharge structure is at least partially in contact with the rotation body.

15. The cutting apparatus of claim 11, wherein the sensor includes a pressure sensor between the charge discharge structure and the driver, the pressure sensor being configured to measure a pressure between the charge discharge structure and the driver.

16. The cutting apparatus of claim 11, wherein the sensor includes a laser sensor configured to measure a distance between the sensor and the charge discharge structure by irradiating a light toward the charge discharge structure.

17. The cutting apparatus of claim 11, wherein the sensor includes a contact type distance sensor that includes a sensor contact portion at least partially in contact with the charge discharge structure and an elastic portion provided at an end portion of the sensor contact portion.

18. The cutting apparatus of claim 11, wherein the driver includes a hydraulic transfer device, and the hydraulic transfer device includes a fluid passage provided in a head portion of the cover and in fluid communication with an internal space within the head portion, the hydraulic transfer device being configured to adjust a pressure within the head portion of the cover to maintain contact between the charge discharge structure and the rotation body.

19. The cutting apparatus of claim 11, wherein a head portion of the cover includes a window including a transparent material that is configured to allow observation of the charge discharge structure.

20. A spindle apparatus, comprising:
a cover;
a rotation body at least partially provided within the cover and rotatable about a central axis of the rotation body, the rotation body including a first end portion exposed to an outside of the cover and a second end portion opposite to the first end portion;
a cutting tool on the first end portion of the rotation body and configured to rotate with the rotation body; and
an electrostatic discharge (ESD) prevention device within the cover and on the second end portion of the rotation body,
wherein the ESD prevention device includes:
a brush on the second end portion of the rotation body, the brush having a groove that faces the rotation body to accommodate the second end portion of the rotation body;
a ground terminal on the brush, the ground terminal being configured to discharge charges accumulated in the cutting tool;
a sensor configured to detect that the brush is in contact with the rotation body; and
a driver on the sensor configured to move the brush such that the brush is brought into contact with the rotation body.
